(19) United States
(12) Patent Application Publication
(10) Pub. No.: US 2014/0174794 A1
(43) Pub. Date: Jun. 26, 2014

(54) HEAT RADIATING SUBSTRATE AND MANUFACTURING METHOD THEREOF

(71) Applicant: Samsung Electro-Mechanics Co., Ltd., Suwon (KR)

(72) Inventors: Joon Seok KANG, Suwon (KR); Kwang Jik Lee, Sungnam (KR); Sang Hyun Shin, Suwon (KR); Hye Suk Shin, Hwasung (KR)

(73) Assignee: Samsung Electro-Mechanics Co., Ltd., Suwon (KR)

(21) Appl. No.: 14/061,266

(22) Filed: Oct. 23, 2013

(30) Foreign Application Priority Data
Dec. 21, 2012 (KR) 10-2012-0150692

(51) Int. Cl. H05K 1/02; C25D 11/02

(52) U.S. Cl. CPC H05K 1/0204; C25D 11/022
USPC 174/252; 205/199

(57) ABSTRACT

A heat radiating substrate having strengthened insulation resistance and heat conductivity, and a manufacturing method thereof. The method for manufacturing a heat radiating substrate includes: preparing a metal substrate; performing an anodizing process on the metal substrate to form an anodic oxidation layer; filling surface pores of the anodic oxidation layer with an insulating material; and forming a metal wiring layer on the anodic oxidation layer. High insulation resistance and heat conductivity can be obtained by filling surface pores formed in an anodizing process with an insulating material.

### CROSS REFERENCE(S) TO RELATED APPLICATIONS

This application claims the benefit under 35 U.S.C. Section 119 of Korean Patent Application Serial No. 10-2012-0150692, entitled “Heat Radiating Substrate and Manufacturing Method thereof” filed on Dec. 21, 2012, which is hereby incorporated by reference in its entirety into this application.

### BACKGROUND OF THE INVENTION

1. Technical Field

The present invention relates to a heat radiating substrate having strengthened insulation resistance and heat conductivity, and a manufacturing method thereof.

2. Description of the Related Art

Electronic components used for automobiles, industrial purposes, and the like have been increased. As electronic components are increasingly reduced in size and become multi-functional, more components may be integrated on a substrate having a small area. Thus, in order to maintain performance of electric components, effective handling of heat generated according to the driving of electronic components is important.

In general, as mentioned in a related art hereinafter, in a circuit board, a primary through hole is formed in a metal core and anodic oxidation coating is formed thereon to form an insulating layer within the through hole and on an aluminum surface. Thereafter, PPG is attached to the anodized aluminum surface to fill the surfaces of both sides and the through hole to form an insulating layer. The through hole is processed as a hole for a via, electroless copper plating, electro copper plating is performed thereon to form a conducive layer, and a substrate is subsequently manufactured. The application of anodizing is to restrain a generation of cracks due to physical shock when the via hole is processed.

However, currently, when a via hole is processed, cracks are still generated, which is, thus, to be solved, such that a heat radiating substrate that can effectively radiate heat and have excellent resistibility is required.

### RELATED ART DOCUMENT

(Patent Document 1) Korean Patent Laid Open Publication No. 2012-0017530

### SUMMARY OF THE INVENTION

An object of the present invention is to provide a heat radiating substrate having high insulating resistance and heat conductivity by filling pores of a surface formed during an anodizing process with an insulating material, and a manufacturing method thereof.

Another object of the present invention is to provide a heat radiating substrate having strengthened insulating resistance and heat conductivity capable of reducing a crack defective rate during a drill process for processing a via hole by filling a via hole and the interior of pores of a surface of an anodic oxidation layer with an insulating material during a process of applying an insulating material.

According to an embodiment of the present invention, there is provided a method for manufacturing a heat radiating substrate including: preparing a metal substrate; performing an anodizing process on the metal substrate to form an anodic oxidation layer; filling surface pores of the anodic oxidation layer with an insulating material; and forming a metal wiring layer on the anodic oxidation layer.

The insulating material filling the surface pores of the anodic oxidation layer may be a liquid crystal polymer (LCP) or any one or more of polybutylene terephthalate, polyethylene terephthalate, aromatic polyamide, polyamide, polycarbonate, polystyrene, polyphenylenesulfide, thermotropic liquid crystal polymer, polysulfone, polyether sulfone, polyetherimide, polyetheretherketone, polyarylate, polymethylmethylacrylate, polyvinylalcohol, polypropylene, polyethylene, polyacrylonitrilebutadienestyrene copolymer, polytetramethyleneoxide-1,4-butandiol copolymer, a copolymer including styrene, fluorinated resin, polyvinylchloride, and polyacrylonitrile.

The copolymer including styrene may be any one or more of SBR, SBS, and ASA, and the fluorinated resin may be any one or more of PVDF, PTFE, and FEP.

The insulating material may fill the surface pores of the anodic oxidation layer having a depth ranging from 10 μm to 100 μm.

According to another embodiment of the present invention, there is provided a method for manufacturing a heat radiating substrate including: preparing a metal substrate; forming a through hole in the metal substrate; performing an anodizing process on the metal substrate with the through hole formed therein to form an anodic oxidation layer; filling surface pores of the anodic oxidation layer and the through hole with an insulating material; removing the insulating material filled in the through hole; and forming a metal wiring layer on the anodic oxidation layer.

In the removing of the insulating material filled in the through hole, the insulating material may be removed by performing a drilling process.

According to another embodiment of the present invention, there is provided a method for manufacturing a heat radiating substrate including: preparing a metal substrate; forming a through hole in the metal substrate; performing a plugging process to fill the through hole with an insulating material; performing an anodizing process on the metal substrate with the through hole formed therein to form an anodic oxidation layer; filling surface pores of the anodic oxidation layer with an insulating material; removing the insulating material filled in the through hole; and forming a metal wiring layer on the anodic oxidation layer.

According to another embodiment of the present invention, there is provided a method for manufacturing a heat radiating substrate including: preparing a metal substrate; performing an anodizing process on the metal substrate to form an anodic oxidation layer; filling surface pores of the anodic oxidation layer with an insulating material; forming a through hole in the metal substrate; performing a plugging process to fill the through hole with an insulating material; removing the insulating material filled in the through hole; and forming a metal wiring layer on the anodic oxidation layer.

In the removing of the insulating material filled in the through hole, the insulating material may be removed by performing a drilling process.

The surface pores of the anodic oxidation layer may be filled with the insulating material by using any one of a screen printing process, a spray process, a slit coating process, and a spin coating process.

The insulating material having viscosity ranging from 4000 cps to 8000 cps and having a printing mesh of 240 to 500 may fill the surface pores of the anodic oxidation layer.

The method may further include: removing the insulating material from the surface of the anodic oxidation layer by using any one of a plasma process, a buffer process, and a polishing process, after the insulating layer is cured, after the filling of the surface pores of the anodic oxidation layer with the insulating layer.

The insulating material filling the surface pores of the anodic oxidation layer may be a liquid crystal polymer (LCP).

According to another embodiment of the present invention, there is provided a heat radiating substrate including: a metal substrate forming a core of the heat radiating substrate; an anodic oxidation layer formed on the metal substrate; an insulating material filling surface pores of the anodic oxidation layer; and a metal wiring layer formed on the anodic oxidation layer.

The metal substrate may include a via hole formed therein, and an inner wall of the via hole may be coated with the insulating material.

The metal substrate may include a via hole formed therein, and an inner wall of the via hole may be coated with a plugged insulating material.

The insulating material having viscosity ranging from 4000 cps to 8000 cps and having a printing mesh of 240 to 500 may fill the surface pores of the anodic oxidation layer, and may be subsequently cured.

A depth of the insulating material filling the surface pores of the anodic oxidation layer may range from 10 μm to 100 μm.

### BRIEF DESCRIPTION OF THE DRAWINGS

FIG. 1 is a flow chart illustrating a method for manufacturing a heat radiating substrate according to an embodiment of the present invention;

FIGS. 2A through 2G are views illustrating a method for manufacturing a heat radiating substrate according to a first embodiment of the present invention;

FIGS. 3A through 3H are views illustrating a method for manufacturing a heat radiating substrate according to a second embodiment of the present invention;

FIGS. 4A through 4H are views illustrating a method for manufacturing a heat radiating substrate according to a third embodiment of the present invention; and

FIGS. 5A and 5B are views illustrating a configuration that pores on a surface of an anodic oxidation layer are filled with an insulating material according to an embodiment of the present invention.

### DESCRIPTION OF THE PREFERRED EMBODIMENTS

Since the present invention may be variously modified and have several exemplary embodiments, specific exemplary embodiments will be shown in the accompanying drawings and be described in detail. However, it is to be understood that the present invention is not limited to the specific exemplary embodiments, but includes all modifications, equivalents, and substitutions included in the spirit and the scope of the present invention.

Terms used in the specification, ‘first’, ‘second’, etc., may be used to describe various components, but the components are not to be construed as being limited to the terms. That is, the terms are used to distinguish one component from another component.

It is to be understood that when one element is referred to as being “connected to” or “coupled to” another element, it may be connected directly to or coupled directly to another element or be connected to or coupled to another element, having the other element intervening therebetween.

Terms used in the present specification are used only in order to describe specific exemplary embodiments rather than limiting the present invention. Singular forms are intended to include plural forms unless the context clearly indicates otherwise. It will be further understood that the terms “comprises” or “have” used in this specification, specify the presence of stated features, steps, operations, components, parts, or a combination thereof, but do not preclude the presence or addition of one or more other features, numerals, steps, operations, components, parts, or a combination thereof.

Hereinafter, exemplary embodiments of the present invention will be described in more detail with reference to the accompanying drawings. In order to facilitate the general understanding of the present invention in describing the present invention, through the accompanying drawings, the same reference numerals will be used to describe the same components and an overlapped description of the same components will be omitted.

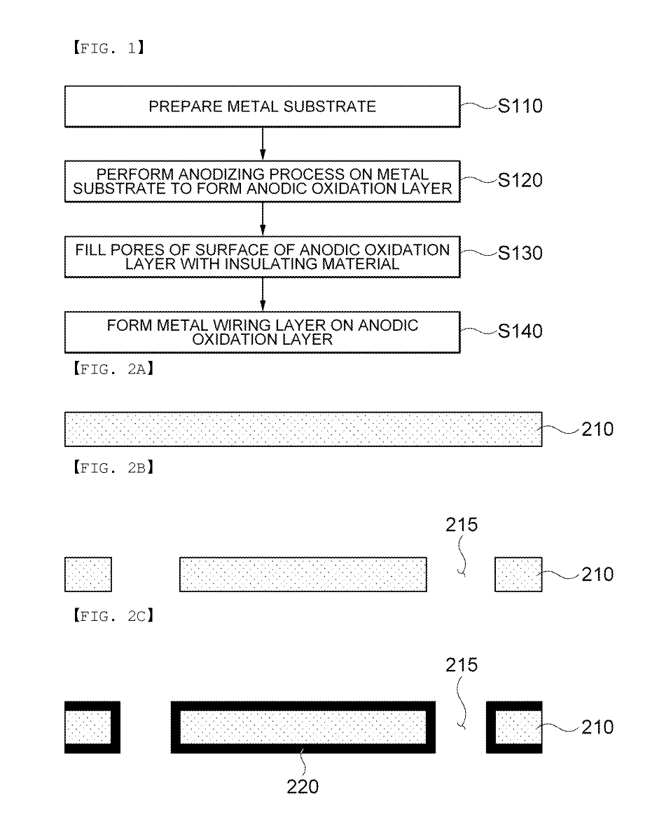

FIG. 1 is a flow chart illustrating a method for manufacturing a heat radiating substrate according to an embodiment of the present invention.

In the present embodiment, in manufacturing a heat radiating substrate, a low-priced aluminum plate, rather than a high-priced ceramic package, is used to reduce production cost, an anodic oxidation layer employing an anodizing method is used to form an insulating layer, pores of a surface of the anodic oxidation layer is filled with an insulating material, and plating is performed thereon, thus enhancing heat radiation performance. In detail, an anodic oxidation layer according to an embodiment of the present invention includes surface pores having a diameter of tens of nanometers, and in this case, the interior of the surface pores, which is generally filled with air, may be filled with an insulating material, instead of air, to enhance an insulating resistance value of a package. Also, a material having excellent heat conductivity may be used as an insulating material to simultaneously enhance insulating resistance and heat conductivity.

Hereinafter, an apparatus for manufacturing a heat radiating substrate may perform the respective processes as follows. The respective processes may not necessarily be performed in time-series order, and even though the order of performing the respective processes is changed, if it satisfies the gist of the present invention, it may be within the scope of the present invention.

In step S110, a metal substrate forming a core layer of a heat radiating substrate is prepared. Here, the metal substrate may be made of aluminum.

In detail, an aluminum plate is prepared by cleaning a contaminant such as an organic substance, or the like, present on a surface thereof. Here, a shape of the aluminum plate is not limited to a particular shape. For example, the aluminum plate may have a square shape, or may have a rectangular shape, a circular shape, or the like, as being processed.

In order to effectively perform a process and secure reliability of a product after performing the process, the aluminum plate may have a thickness ranging from 0.1 mm to 5 mm. A size of the heat radiating substrate may be changed according to processing capability of a production line and a configuration density of a package.

In step S120, an anodizing process is performed on the metal substrate to form an anodic oxidation layer. The anodic oxidation layer may be formed on one surface or both surfaces of the metal substrate. Before or after this step, a through hole may be processed in a required portion. Here, the anodic oxidation layer may be an electrical insulating layer such as Al₂O₃.

In step S130, surface pores of the anodic oxidation layer are filled with an insulating material. In the present embodiment, in order to increase an insulation resistance value and heat conductivity of the heat radiating substrate, a structure and a process capable of enhancing insulation resistance and heat conductivity by filling the surface pores of the anodic oxidation layer with an insulating material, e.g., a liquid crystal polymer (LCP).

Referring to FIGS. 5A and 5B, a state in which surface pores 517 of the anodic oxidation layer 515 formed on the metal substrate 510 is filled with an insulating material 520. Here, the insulating material may fill the surface pores 517 of the anodic oxidation layer 515 with viscosity ranging from 4000 to 8000 cps, by which the insulating material is properly dispersed, and with printing mesh ranging from 240 to 500, and may be cured.

Namely, the insulating material 520 is coated to be thin on the anodic oxidation layer 515 with at viscosity less than 8000 cps and by using a printing mesh of 240 or more, and left at room temperature to allow the insulating material 520 to flow to fill the surface pores 517 of the anodic oxidation layer 515, and a temperature is gradually increased from room temperature such that no crack is generated in the anodic oxidation layer 515 during a process of curing the insulating material 520.

Besides, an insulating material filling the surface pores of the anodic oxidation layer 515 may be one or more of polybutylene terephthalate, polyethylene terephthalate, aromatic polyamide, polyamide, polycarbonate, polystyrene, polyphenylenesulfide, thermotropic liquid crystal polymer, polysulfone, polyether sulfone, polyetherimide, polyetheretherketone, polyarylate, polymethylmethylacrylate, polyvinylalcohol, polypropylene, polyethylene, polyacrylonitrilebutadienestyrene copolymer, polytetramethyleneoxide-1,4-butandiol copolymer (polybutyleneterephtalate elastic body), a copolymer including styrene, fluorinated resin, polyvinylchloride, and polyacrylonitrile.

Here, the copolymer including styrene may be any one or more of SBR, SBS, and ASA, and the fluorinated resin may be any one or more of PVDF, PTFE, and FEP.

Hereinafter, a case in which an insulating material is LCP will be described for the purpose of description.

LCP may fill the surface pores of the anodic oxidation layer by using any one of a screen printing process, a spray process, a slit coating process, and a spin coating process.

Also, after the surface pores of the anodic oxidation layer are filled with LCP, LCP may be cured, and subsequently removed from the surface of the anodic oxidation layer by using any one of a plasma process, a buffer process, and a polishing process, such that LCP remain only in the surface pores of the anodic oxidation layer, whereby a thickness of an LCP layer formed on the surface of the anodic oxidation layer may be minimized to secure high heat conductivity and secure adhesion of a metal wiring, e.g., a copper wiring, afterwards. In step S140, a metal wiring layer is formed on the anodic oxidation layer.

Besides, as described hereinafter, after the surface pores of the anodic oxidation layer are filled with LCP, a via drilling process, a plugging process, a seed layer sputtering process, a copper plating process, a circuit patterning process, or the like, is performed thereon to complete a package substrate.

In this manner, in the present embodiment, surface saturation of the anodic oxidation layer is filled with a particular material to remove an air layer, adhesion of the plated layer formed on the anodic oxidation layer may be enhanced. Here, in case that the anodic oxidation layer is saturated, LCP may fill to have a depth ranging from 10 μm to 100 μm.

Also, in the present embodiment, since a metal core such as aluminum having excellent heat conductivity is used, heat radiation performance may be enhanced.

A general flow chart illustrating a method for manufacturing a heat radiating substrate has been described, and hereinafter, a specific embodiment of a method for manufacturing a heat radiating substrate according to an embodiment of the present invention will be described. Hereinafter, respective embodiments will be described in turn, and the present invention is not limited thereto.

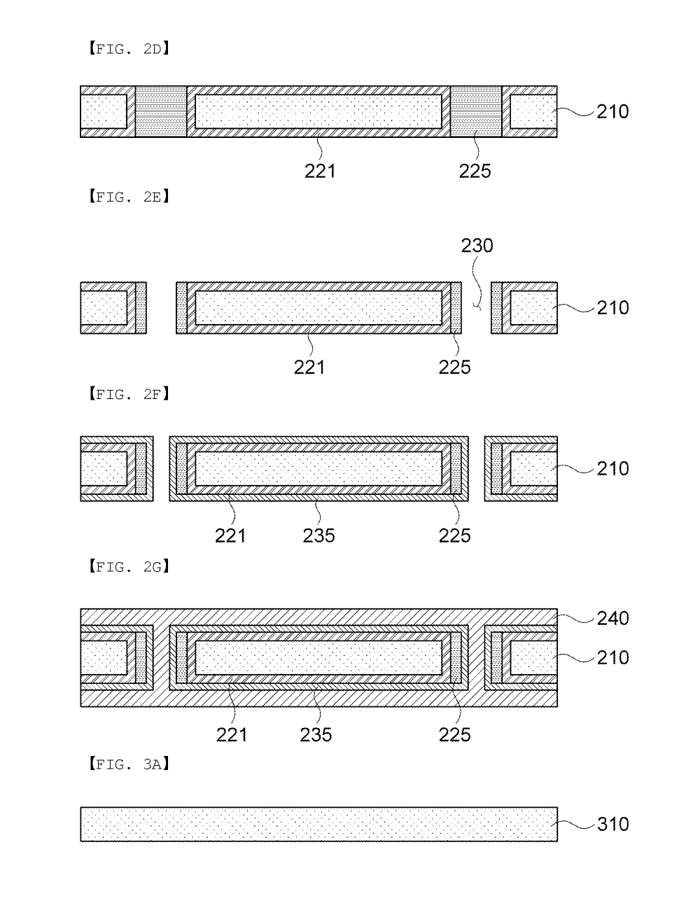

FIGS. 2A through 2G are views illustrating a method for manufacturing a heat radiating substrate according to a first embodiment of the present invention. Referring to FIGS. 2A through 2G, a metal substrate 210, a through hole 215, an anodic oxidation layer 220, a surface-coated anodic oxidation layer 221, an insulating material 225, a via hole 230, a seed layer 235, and a conductive layer 240 are illustrated.

In the present embodiment, a process of forming the through hole 215 and sequentially forming the anodic oxidation layer 220 and the insulating material 225 will be performed in order.

Referring to FIG. 2A, the metal substrate 210 forming a core layer of the heat radiating substrate is prepared. Referring to FIG. 2B, the through hole 215 is formed in the metal substrate 210. The through hole 215 may be a hole for forming the via hole 230.

Referring to FIG. 2C, an anodizing process is performed on the metal substrate 210 with the through hole 215 formed therein, to form the anodic oxidation layer 220.

Referring to FIG. 2D, the surface pores of the anodic oxidation layer 220 and the through hole 215 are filled with the insulating material 225, and in this case, the anodic oxidation layer 221 with the insulating material coated on a surface thereof is formed. As mentioned above, the insulating material 225 may flow into the surface pores of the anodic oxidation layer 220 and may be cured to form the surface-coated anodic oxidation layer 221.

Referring to FIG. 2E, after the insulating material 225 is cured, the insulating material 225 filled in the through hole 215 is removed. Here, in order to remove the insulating material 225 from the through hole 215, a drilling process for forming the via hole 230 may be performed. Here, an inner wall of the via hole 230 may be coated with the insulating material 225.

Referring to FIG. 2F, a predetermined metal, e.g., copper, is sputtered on the anodic oxidation layer 220 to form the seed layer 235. Referring to FIG. 2G, the conductive layer 240 may be formed on the seed layer 235 to form a metal wiring layer. Here, the metal wiring layer may be formed through copper plating and circuit patterning.

In the foregoing embodiment, since the through hole 215 is filled with the insulating material 225, the via hole 230 may not be anodized, and since the surface pores of the anodic oxidation layer 220 is filled with the insulating material 225, crack defect rate may be lowered in the drilling process.

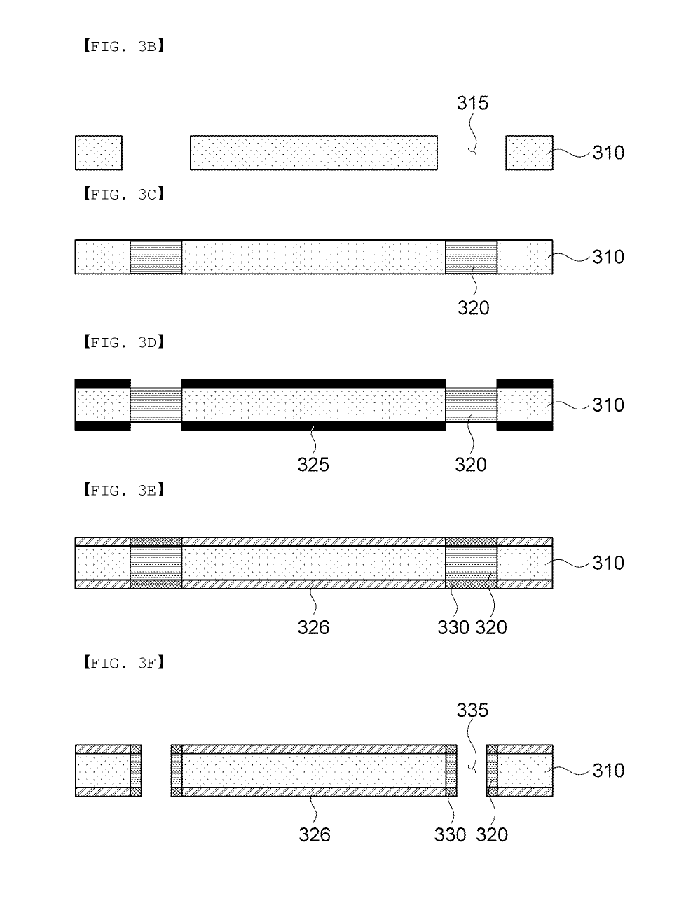

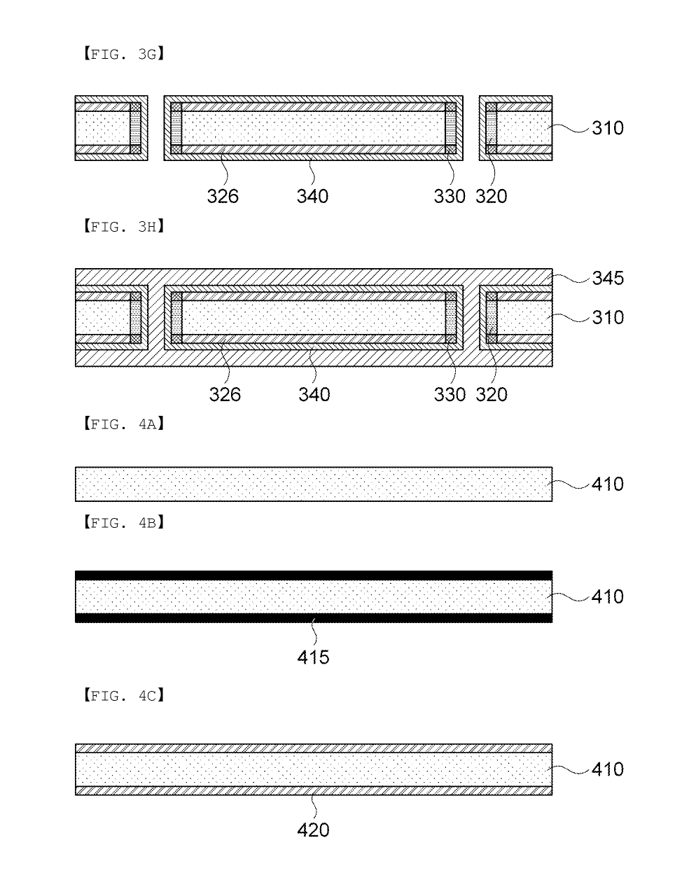

FIGS. 3A through 3H are views illustrating a method for manufacturing a heat radiating substrate according to a second embodiment of the present invention. Referring to FIGS. 3A through 3H, a metal substrate 310, a through hole 315, an insulating material 320, an anodic oxidation layer 325, a surface-coated anodic oxidation layer 326, an insulating material 330, a via hole 335, a seed layer 340, and a conductive layer 345 are illustrated.

In the present embodiment, a process of forming the through hole 315, performing a plugging process, and subsequently forming the anodic oxidation layer 325 and the insulating material 330 will be performed in order.

Referring to FIG. 3A, the metal substrate 310 forming a core layer of the heat radiating substrate is prepared. Referring to FIG. 3B, the through hole 315 is formed in the metal substrate 310.

Referring to FIG. 3C, a plugging process is performed to fill the through hole 315 with the insulating material 320 such as insulating ink. Referring to FIG. 3D, an anodizing process is performed on the metal substrate 310 with the through hole 315 formed therein, to form the anodic oxidation layer 325.

Referring to FIG. 3E, the surface pores of the anodic oxidation layer 325 are filled with the insulating material 330 to form a surface-coated anodic oxidation layer 326, and the insulating material 330 is coated on a surface of the insulating material 320.

Referring to FIG. 3F, the insulating material 320 filled in the through hole 315 is removed. Here, in order to remove the insulating material 320 from the through hole 315, a drilling process for forming the via hole 335 may be performed. Here, an inner wall of the via hole 335 may be coated with the insulating material 320.

Referring to FIG. 3G, a metal such as copper is sputtered on the anodic oxidation layer 325 to form the seed layer 340. Referring to FIG. 3H, the conductive layer 345 may be formed on the seed layer 340 to form a metal wiring layer.

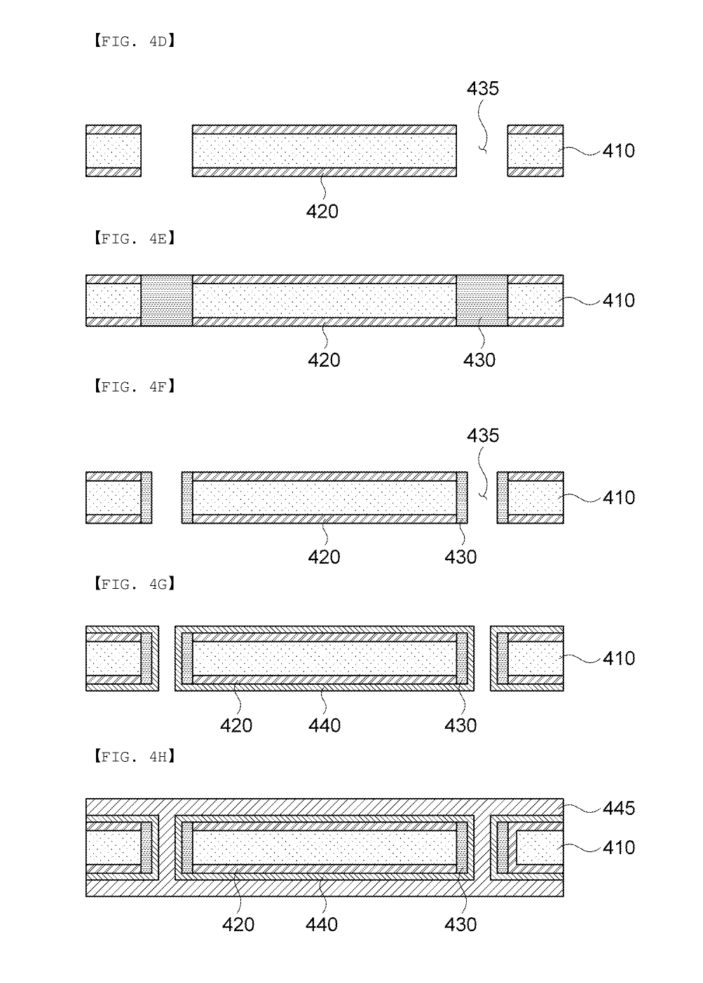

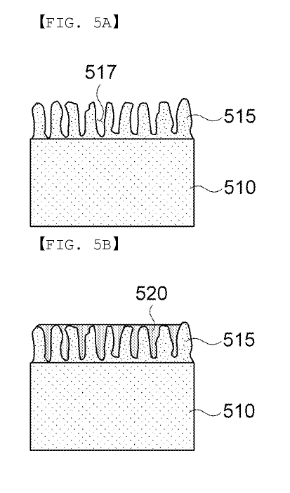

FIGS. 4A through 4H are views illustrating a method for manufacturing a heat radiating substrate according to a third embodiment of the present invention. Referring to FIGS. 4A through 4H, a metal substrate 410, an anodic oxidation layer 415, a surface-coated anodic oxidation layer 420, a through hole 425, an insulating material 430, a via hole 435, a seed layer 440, and a conductive layer 445 are illustrated.

In the present embodiment, after an insulating material is coated on the anodic oxidation layer 415 to form the surface-coated oxidation layer 430, a through hole 425 process and a plugging process are subsequently performed in order.

Referring to FIG. 4A, the metal substrate 410 forming a core layer of the heat radiating substrate is prepared. Referring to FIG. 4B, an anodizing process is performed on the metal substrate 410 to form the anodic oxidation layer 415. Referring to FIG. 4C, the surface pores of the anodic oxidation layer 415 are filled with an insulating material to form a surface-coated anodic oxidation layer 420.

Referring to FIG. 4D, the through hole 425 is formed in the metal substrate 410 on which the anodic oxidation layer 415 with the surface pores filled with an insulating material has been coated.

Referring to FIG. 4E, a plugging process is performed to fill the through hole 425 with the insulating material 430 such as insulating ink. Referring to FIG. 4F, before or after the insulating material 430 is cured, the insulating material 430 filled in the through hole 425 is removed to form the via hole 435. Here, a drilling process for forming the via hole 435 may be performed. Here, an inner wall of the via hole 435 may be coated with the insulating material 430.

Referring to FIG. 4G, a metal such as copper is sputtered on the anodic oxidation layer 415 to form the seed layer 440. Referring to FIG. 4H, the conductive layer 445 may be formed on the seed layer 440 to form a metal wiring layer.

The method for manufacturing a heat radiating substrate having strengthened insulation resistance and heat conductivity may be implemented in the form of a program command that may be performed through various computer units and recorded in a computer-readable medium. Namely, the recording medium may be a computer-readable recording medium storing a program for executing the foregoing respective steps in a computer.

The computer-readable medium may include a program command, a data file, a data structure, and the like, alone or in a form of a combination thereof. A program command recorded in the medium may be particularly designed or configured for the present invention or may be known to be used by a computer software person in the art. Examples of the computer-readable recording medium include a hardware device particularly configured to store and perform a program command, such as a magnetic medium such as a hard disk, a floppy disk, or a magnetic tape, an optical medium such as a CD-ROM or a DVD, a magneto-optical medium such as a floptical disk, and a ROM, a RAM, a flash memory, or the like.

In the case of the heat radiating substrate having strengthened insulation resistance and heat conductivity and the manufacturing method thereof according to the embodiments of the present invention, surface pores formed in an anodizing process are filled with an insulating material, obtaining high insulation resistance and heat conductivity.

Also, in the case of the heat radiating substrate having strengthened insulation resistance and heat conductivity and the manufacturing method thereof according to the embodiments of the present invention, the via hole may be filled with an insulating material in the process of applying an insulating material and the interior of the surface pores of the anodic oxidation layer may also be filled with an insulating material, a crack defect rate may be lowered in the drilling process for a via hole.

Although the preferred embodiments of the present invention have been disclosed for illustrative purposes, those skilled in the art will appreciate that various modifications, additions, and substitutions are possible, without departing from the scope and spirit of the invention as disclosed in the accompanying claims. Accordingly, such modifications, additions and substitutions should also be understood to fall within the scope of the present invention.

1. A heat radiating substrate comprising:
a metal substrate forming a core of the heat radiating substrate;
an anodic oxidation layer formed on the metal substrate;
an insulating material filling surface pores of the anodic oxidation layer; and
a metal wiring layer formed on the anodic oxidation layer.

2. The heat radiating substrate according to claim 1, wherein the metal substrate includes a via hole formed therein, and an inner wall of the via hole is coated with the insulating material.

3. The heat radiating substrate according to claim 1, wherein the metal substrate includes a via hole formed therein, and an inner wall of the via hole is coated with a plugged insulating material.

4. The heat radiating substrate according to claim 1, wherein the insulating material having viscosity ranging from 4000 cps to 8000 cps and having a printing mesh of 240 to 500 fills the surface pores of the anodic oxidation layer, and is subsequently cured.

5. The heat radiating substrate according to claim 1, wherein a depth of the insulating material filling the surface pores of the anodic oxidation layer ranges from 10 μm to 100 [2m.

6. The heat radiating substrate according to claim 1, wherein the insulating material filling the surface pores of the anodic oxidation layer is a liquid crystal polymer (LCP).

7. A method for manufacturing a heat radiating substrate, the method comprising:
preparing a metal substrate;
performing an anodizing process on the metal substrate to form an anodic oxidation layer;
filling surface pores of the anodic oxidation layer with an insulating material; and
forming a metal wiring layer on the anodic oxidation layer.

8. The method according to claim 7, wherein the insulating material filling the surface pores of the anodic oxidation layer is a liquid crystal polymer (LCP).

9. The method according to claim 7, wherein the insulating material filling the surface pores of the anodic oxidation layer is any one or more of polybutylene terephthalate, polyethylene terephthalate, aromatic polyamide, polyamide, polycarbonate, polystyrene, polyphenylenesulfide, thermotropic liquid crystal polymer, polysulfone, polyether sulfone, polyetherimide, polyetheretherketone, polyarylate, polymethylmethylacrylate, polyvinylalcohol, polypropylene, polyethylene, polyacrylonitrilebutadienestyrene copolymer, polytetramethyleneoxide-1,4-butandiol copolymer, a copolymer including styrene, fluorinated resin, polyvinylchloride, and polyacrylonitrile.

10. The method according to claim 9, wherein the copolymer including styrene is any one or more of SBR, SBS, and ASA.

11. The method according to claim 9, wherein the fluorinated resin is any one or more of PVDF, PTFE, and FEP.

12. The method according to claim 7, wherein the insulating material fills the surface pores of the anodic oxidation layer having a depth ranging from 10 μm to 100 μm.

13. A method for manufacturing a heat radiating substrate, the method comprising:
preparing a metal substrate;
forming a through hole in the metal substrate;
performing an anodizing process on the metal substrate with the through hole formed therein to form an anodic oxidation layer;
filling surface pores of the anodic oxidation layer and the through hole with an insulating material;
removing the insulating material filled in the through hole; and
forming a metal wiring layer on the anodic oxidation layer.

14. The method according to claim 13, wherein in the removing of the insulating material filled in the through hole, the insulating material is removed by performing a drilling process.

15. A method for manufacturing a heat radiating substrate, the method comprising:
preparing a metal substrate;
forming a through hole in the metal substrate;
performing a plugging process to fill the through hole with an insulating material;
performing an anodizing process on the metal substrate with the through hole formed therein to form an anodic oxidation layer;
filling surface pores of the anodic oxidation layer with an insulating material;
removing the insulating material filled in the through hole; and
forming a metal wiring layer on the anodic oxidation layer.

16. A method for manufacturing a heat radiating substrate, the method comprising:
preparing a metal substrate;
performing an anodizing process on the metal layer to form an anodic oxidation layer;
filling surface pores of the anodic oxidation layer with an insulating material;
forming a through hole with an insulating material;
performing a plugging process to fill the through hole with an insulating material;
removing the insulating material filled in the through hole; and
forming a metal wiring layer on the anodic oxidation layer.

17. The method according to claim 15, wherein in the removing of the insulating material filled in the through hole, the insulating material is removed by performing a drilling process.

18. The method according to claim 13, wherein the surface pores of the anodic oxidation layer are filled with the insulating material by using any one of a screen printing process, a spray process, a slit coating process, and a spin coating process.

19. The method according to claim 18, wherein the insulating material having viscosity ranging from 4000 cps to 8000 cps and having a printing mesh of 240 to 500 fills the surface pores of the anodic oxidation layer.

20. The method according to claim 13, further comprising:
removing the insulating material from the surface of the anodic oxidation layer by using any one of a plasma process, a buffer process, and a polishing process, after the insulating layer is cured, after the filling of the surface pores of the anodic oxidation layer with the insulating layer.

21. The method according to claim 13, wherein the insulating material filling the surface pores of the anodic oxidation layer is a liquid crystal polymer (LCP).

22. The method according to claim 16, wherein in the removing of the insulating material filled in the through hole, the insulating material is removed by performing a drilling process.

23. The method according to claim 15, wherein the surface pores of the anodic oxidation layer are filled with the insulating material by using any one of a screen printing process, a spray process, a slit coating process, and a spin coating process.

24. The method according to claim 16, wherein the surface pores of the anodic oxidation layer are filled with the insulating material by using any one of a screen printing process, a spray process, a slit coating process, and a spin coating process.

25. The method according to claim 15, further comprising:
removing the insulating material from the surface of the anodic oxidation layer by using any one of a plasma process, a buffer process, and a polishing process, after the insulating layer is cured, after the filling of the surface pores of the anodic oxidation layer with the insulating layer.

26. The method according to claim 16, further comprising:
removing the insulating material from the surface of the anodic oxidation layer by using any one of a plasma process, a buffer process, and a polishing process, after the insulating layer is cured, after the filling of the surface pores of the anodic oxidation layer with the insulating layer.

27. The method according to claim 15, wherein the insulating material filling the surface pores of the anodic oxidation layer is a liquid crystal polymer (LCP).

28. The method according to claim 16, wherein the insulating material filling the surface pores of the anodic oxidation layer is a liquid crystal polymer (LCP).
